(19) United States
(12) Patent Application Publication
(10) Pub. No.: US 2017/0345734 A1
(43) Pub. Date: Nov. 30, 2017

(54) Thermally Conductive Sheet

(71) Applicants: POLYMATECH JAPAN CO., LTD., Saitama-city, Saitama (JP); PANASONIC INTELLECTUAL PROPERTY MANAGEMENT CO., LTD., Osaka-shi, Osaka (JP)

(72) Inventors: Yasuyoshi Watanabe, Saitama-city, Saitama (JP); Yoshiya Sakaguchi, Kyoto (JP); Masafumi Nakayama, Hokkaido (JP)

(73) Assignees: POLYMATECH JAPAN CO., LTD., Saitama-city, Saitama (JP); PANASONIC INTELLECTUAL PROPERTY MANAGEMENT CO., LTD., Osaka-shi, Osaka (JP)

(21) Appl. No.: 15/536,222

(22) PCT Filed: Dec. 1, 2015
(86) PCT No.: PCT/JP2015/083781

§ 371 Date: Jun. 15, 2017

(30) Foreign Application Priority Data
Dec. 25, 2014 (JP) 2014-263168

(51) Int. Cl. H01L 23/373; H05K 7/20; C08K 3/04; C09K 5/14

(52) U.S. Cl. CPC H01L 23/3733; C09K 5/14; H05K 7/2039; C08K 3/04; C08K 2201/001; C08K 2201/005; C08K 2201/006

(57) ABSTRACT

The thermally conductive sheet includes a sheet-like formed body produced by curing a mixed composition containing an uncured polymer matrix, a flat graphite powder, and a thermally conductive filler having an aspect ratio of 2 or less, flat surfaces of particles of the flat graphite powder being aligned in a thickness direction of the sheet. The thermally conductive sheet contains the thermally conductive filler together with the flat graphite powder and thus contains the thermally conductive material densely charged and has good flexibility and good tackiness on the surfaces of the sheet.

### TECHNICAL FIELD

The present invention relates to a thermally conductive sheet arranged and used between a heat-generating body and a heat-dissipating body.

### BACKGROUND ART

Heat-dissipating bodies such as heatsinks are used for electronic devices, such as computers and automobile parts, in order to dissipate heat generated from heat-generating bodies, such as semiconductor elements and mechanical parts. To enhance the efficiency of the heat transfer to the heat-dissipating bodies, thermally conductive sheets are arranged between heat-generating bodies and heat-dissipating bodies, in some cases. An example of such a thermally conductive sheet is disclosed in Japanese Unexamined Patent Application Publication No. 2014-027144 (PTL 1) that discloses a thermally conductive sheet in which graphitized carbon fibers serving as a thermally conductive material are charged and aligned.

### CITATION LIST

### Patent Literature

PTL 1: Japanese Unexamined Patent Application Publication No. 2014-027144

### SUMMARY OF INVENTION

### Technical Problem

However, when such a thermally conductive sheet in which carbon fibers are aligned is highly flexible, the alignment of the carbon fibers tends to be disturbed in a highly compressed state. This phenomenon is inevitable because the entire thermally conductive sheet is deformed so as to extend outward as the thermally conductive sheet is compressed. This deformation disadvantageously causes the alignment of the carbon fibers to be disturbed to reduce the thermal conductivity. To align carbon fibers, carbon fibers shorter than the thickness of the sheet are used. To bring the short carbon fibers into contact with each other to form a heat conduction path extending from one surface to the other surface of the sheet, the carbon fibers need to be densely charged. It is, however, difficult to densely charge the carbon fibers to achieve a desired thermal conductivity in view of, for example, the production method and hardness.

The present invention has been accomplished in light of the foregoing problems. It is an object of the present invention to provide a thermally conductive sheet having a higher thermal conductivity than conventional thermally conductive sheets. It is another object of the present invention to provide a flexible thermally conductive sheet having an improved thermal conductivity.

### Solution to Problem

A thermally conductive sheet of the present invention to achieve the objects has a structure described below.

Provided is a thermally conductive sheet including a sheet-like formed body produced by curing a mixed composition containing an uncured polymer matrix, a flat graphite powder, and a thermally conductive filler having an aspect ratio of 2 or less, the flat surfaces of particles of the flat graphite powder being aligned in a thickness direction of the sheet.

Because the flat graphite powder and the thermally conductive filler having an aspect ratio of 2 or less are contained in the uncured polymer matrix, both the flat graphite powder and the thermally conductive filler can be more densely charged than when the flat graphite powder or the thermally conductive filler is charged alone. This results in a high thermal conductivity. Because of the cured body of the mixed composition containing the uncured polymer matrix, the flat graphite powder, and the thermally conductive filler having an aspect ratio of 2 or less, the thermally conductive sheet has a good alignment of the flat graphite powder.

Because the flat surfaces of the particles of the flat graphite powder are aligned in the thickness direction, the sheet has a good thermal conductivity in the thickness direction and can also transfer heat toward side surfaces. Let us compare the sheet with a thermally conductive sheet including aligned graphitized carbon fibers. When carbon fibers are used, a good thermal conductivity is provided in the thickness direction of the sheet, which is the axial direction of carbon fibers; however, the axial direction is only one direction. In contrast, when the flat graphite powder is used, the thermal conductivity is provided in the planar direction of the particles of the flat graphite powder; hence, the thermal conductivity can be provided in the plane direction, which is not limited to one direction. The high thermal conductivity in the plane direction seems to be effective in promoting heat conduction between the particles of the graphite powder to increase the heat conduction in the alignment direction.

In the thermally conductive sheet including aligned carbon fibers, carbon fibers shorter than the thickness of the sheet are used in view of the orientation properties and flexibility. Regarding a path through which heat is conducted in the thickness direction, heat is inevitably conducted through multiple carbon fibers; thus, contact of carbon fibers with each other also needs to be considered. The lines of carbon fibers need to overlap one another in such a thermally conductive sheet including aligned carbon fibers, whereas the planes overlap one another in the thermally conductive sheet including the flat graphite powder. This seems to lead to a significantly higher probability of contact. Accordingly, the aligned particles of the flat graphite powder have a higher efficiency of heat conduction than aligned carbon fibers.

In the thermally conductive sheet including the carbon fibers, the carbon fibers are easily bent by compression in the direction of the fiber axis. In contrast, in the thermally conductive sheet including the flat graphite powder, the particles of the flat graphite powder are not easily bent because the directions of the normals to the flat surfaces of the particles of the flat graphite powder extend randomly with respect to the thickness direction of the sheet. Thus, the sheet can have a stable thermal conductivity.

In the thermally conductive sheet, the uncured polymer matrix may contain a liquid silicone serving as a main component and a curing agent.

Regarding the thermally conductive sheet, in the case of the uncured polymer matrix containing a liquid silicone serving as a main component and a curing agent, a low viscosity can be achieved prior to the curing; thus, the flat graphite powder and the thermally conductive filler can be easily charged, thereby resulting in the thermally conductive sheet having a high degree of alignment.

In the thermally conductive sheet, the flat graphite powder may be composed of an artificial graphite produced by thermal decomposition of a polymer film by firing.

In the case where the artificial graphite produced by thermal decomposition of the polymer film by firing is used as the flat graphite powder, the thermal conductivity of the thermally conductive sheet is easily increased because the artificial graphite has a higher thermal conductivity than natural graphite.

In the thermally conductive sheet, the flat graphite powder may have a specific surface area of 0.70 to 1.50 m²/g.

In the case where the flat graphite powder has a specific surface area of 0.70 to 1.50 m²/g, the mixed composition having an appropriate viscosity can be produced, thus resulting in the thermally conductive sheet that contains the flat graphite powder densely charged and that has a high thermal conductivity.

In the thermally conductive sheet, with respect to a particle size distribution of the flat graphite powder in terms of surface-area frequency, the flat graphite powder may have a peak in the range of 20 to 400 μm, and the ratio of a maximum frequency in the range of 200 to 400 μm to a maximum frequency in the range of 20 to 150 μm may be 0.2 to 2.0.

In the case where, with respect to the particle size distribution of the flat graphite powder in terms of surface-area frequency, the flat graphite powder used has a peak in the range of 20 to 400 μm and the ratio of a maximum frequency in the range of 200 to 400 μm to a maximum frequency in the range of 20 to 150 μm is 0.2 to 2.0, the mixed composition having an appropriate viscosity can be produced, resulting in the thermally conductive sheet that includes the flat graphite powder densely charged and that has a high thermal conductivity.

In the thermally conductive sheet, with respect to a particle size distribution of the flat graphite powder in terms of surface-area frequency, the surface-area frequency at 800 μm or more may be 0.1% or less.

In the case where, with respect to the particle size distribution of the flat graphite powder used in terms of surface-area frequency, the surface-area frequency at 800 μm or more of the flat graphite powder is 0.1% or less, the mixed composition having an appropriate viscosity can be produced, resulting in the thermally conductive sheet that includes the flat graphite powder densely charged and that has a high thermal conductivity.

The flat graphite powder having a particle size of a 800 μm or more is highly likely to disturb the alignment. A high proportion of the flat graphite powder having the particle size results in an increase in the risk of decreasing the thermal conductivity due to the disturbance of the alignment. However, when the proportion of the flat graphite powder having a particle size of 800 μm or more is 0.1% or less, an appropriate viscosity is obtained as described above. Thus, even when the flat graphite powder is densely charged, the alignment is less likely to be disturbed.

In the thermally conductive sheet, the thermally conductive filler may have an average particle size of 0.5 to 35 μm.

In the case where the thermally conductive filler has an average particle size of 0.5 to 35 μm, the thermally conductive filler can be densely charged together with the flat graphite powder, thus resulting in a high thermal conductivity.

In the thermally conductive sheet, the mixed composition may contain 75 to 135 parts by mass of the flat graphite powder and 250 to 700 parts by mass of the thermally conductive filler per 100 parts by mass of the uncured polymer matrix.

In the case where the mixed composition is produced so as to contain 75 to 135 parts by mass of the flat graphite powder and 250 to 700 parts by mass of the thermally conductive filler per 100 parts by mass of the uncured polymer matrix, the mixed composition can have good dispersibility and an appropriate viscosity while the flat graphite powder and the thermally conductive filler are densely charged, thus resulting in the thermally conductive sheet having good alignment and thermal conductivity.

In the thermally conductive sheet, directions of normals to the flat surfaces of the particles of the flat graphite powder may extend randomly and parallel to a flat surface of the thermally conductive sheet.

In the case where the thermally conductive sheet can be produced in such a manner that the directions of the normals to the flat surfaces of the particles of the flat graphite powder extend randomly and parallel to the flat surface of the thermally conductive sheet, the thermally conductive sheet in which delamination is less likely to occur between the particles of the flat graphite powder and which is not anisotropic with respect to the direction of the flat surface of the sheet can be obtained.

The thermally conductive sheet may have a type OO hardness, specified by ASTM D2240, of 10 to 80, a thermal conductivity of 12 to 30 W/m·K in the thickness direction of the sheet, and a coefficient of static friction of 8.0 to 20.0 against a mirror-finished stainless steel surface.

In the case where the thermally conductive sheet has a type OO hardness, specified by ASTM D2240, of 10 to 80, a thermal conductivity of 12 to 30 W/m·K in the thickness direction of the sheet, and a coefficient of static friction of 8.0 to 20.0 against a mirror-finished stainless steel surface, the thermally conductive sheet is flexible and has high adhesion to an adherend and good thermal conductivity.

### Advantageous Effects of Invention

The thermally conductive sheet according to the present invention has good flexibility and thermal conductivity. Furthermore, the thermally conductive sheet is easily fixed to a heat-generating body and a heat-dissipating body and has good workability.

### BRIEF DESCRIPTION OF DRAWINGS

FIG. 1 is a graph illustrating a particle size distribution of a flat graphite powder in terms of surface-area frequency.

FIG. 2 is a schematic diagram of an experimental apparatus to measure a coefficient of static friction.

### DESCRIPTION OF EMBODIMENTS

The present invention will be described in more detail by embodiments. In the embodiments, redundant descriptions of the same material, composition, production method, effect, and so forth are omitted.

A thermally conductive sheet of this embodiment includes a sheet-like formed body produced by curing a mixed composition containing an uncured polymer matrix, a flat graphite powder, and a thermally conductive filler having an aspect ratio of 2 or less, flat surfaces (flat planes) of particles of the flat graphite powder being aligned in a thickness direction of the sheet.

### <Polymer Matrix>

A polymer matrix contains a polymer such as a resin or rubber and is a body obtained by curing the uncured polymer matrix. The uncured polymer matrix is a liquid polymer composition and may be composed of a mixture system containing a main component and a curing agent. Thus, the polymer composition may contain, for example, an uncross-linked rubber and a cross-linking agent or may contain an uncross-linked rubber containing a cross-linking agent and a cross-linking promoter. The curing reaction may be performed at normal temperature or under heating. When the polymer matrix is a silicone rubber, examples thereof include alkenyl group-containing organopolysiloxanes and organohydrogenpolysiloxanes. In the case of a polyester-based thermoplastic elastomer, a diol and a dicarboxylic acid may be used. In the case of a polyurethane-based thermoplastic elastomer, a diisocyanate and a diol may be used. Among these uncured polymer matrices, an additive reaction-type silicone rubber in which the polymer matrix after curing is particularly soft and in which the thermally conductive filler is well charged is preferably used.

### <Flat Graphite Powder>

The flat graphite powder in the polymer matrix contains graphite powder particles having a flat shape, such as a scaly or planar shape. Each of the particles of the flat graphite powder has a crystal face of graphite, the crystal face extending in the planar direction, and each particle having a very high isotropic thermal conductivity in the plane. Thus, by aligning the planar directions thereof, the thermal conductivity in a specific direction can be increased.

Examples of the graphite include natural graphite and artificial graphite. A flat graphite powder obtained by pulverizing an artificial graphite sheet, which is produced by thermal decomposition of a polymer film, (hereinafter, referred to as a “film pyrolysis sheet”) is preferably used. The film pyrolysis sheet has a high thermal conductivity particularly in the planar direction of the sheet. The flat graphite powder obtained by pulverizing the film pyrolysis sheet also has a very high thermal conductivity.

The film pyrolysis sheet can be obtained by firing the polymer film at a high temperature of 2,400° C. to 3,000° C. in an inert gas. The firing may be performed in one step or two or more steps. The inert gas is preferably, but not necessarily, nitrogen or argon.

The polymer film to be graphitized is preferably, but not necessarily, an aromatic polymer such as polyimide because a high-thermal-conductivity graphite film having a developed graphite structure can be obtained. The thickness of the polymer film can be selected, depending on a required thickness of the particles of the flat graphite powder, and is preferably 400 μm or less, more preferably 10 to 200 μm. However, because delamination can occur between graphite layers when graphite is pulverized, the thickness of each particle of the flat graphite powder can be smaller than that of the polymer film.

A method for pulverizing the film pyrolysis sheet is not limited to any particular method. For example, the film pyrolysis sheet can be pulverized by a ball mill process, a Nanomizer process, a jet mill process, or a pin mill process. A large sized flat graphite powder is preferably produced in advance by a shearing process with a blade. When natural graphite is used, a graphite having a predetermined aspect ratio is processed so as to have a flat shape. As the flat graphite powder, a single type of flat graphite powder produced by the same production process may be used alone. Different types of flat graphite powders produced by different production processes or from different origins may be used in combination as a mixture. Flat graphite powders having different particle size distributions may be mixed together.

The particles of the flat graphite powder preferably have an aspect ratio more than 2. This is because at an aspect ratio of 2 or less, it is difficult to align the particles of the flat graphite powder in a specific direction and thus to increase the thermal conductivity. More preferably, the aspect ratio is 5 or more. The term “aspect ratio” used here refers to the value of “the length of the long axis of a flat surface/thickness” of each of the particles of the flat graphite powder.

The flat graphite powder preferably has a specific surface area of 0.70 to 1.50 m²/g, more preferably 0.85 to 1.50 m²/g. The specific surface area is also closely related to the particle size. At a specific surface area less than 0.70 m²/g, a relative amount of the flat graphite powder having a large particle size is excessively increased, thus possibly disturbing the alignment. Furthermore, the proportion of the flat graphite powder having a large size of 800 μm or more tends to be increased to lead to a high viscosity. In other words, the flat graphite powder having a large size is difficult to densely charge when the viscosity is adjusted to a desired viscosity. Although it is generally considered that the use of a flat graphite powder having a larger particle size easily increases the thermal conductivity, the fact is that the use of a flat graphite powder having a larger particle size does not easily increase the thermal conductivity in view of the amount charged and alignment. At a specific surface area more than 1.50 m²/g, the viscosity tends to increase because of a high fine particle content. It is thus difficult to densely charge the flat graphite powder and to increase the thermal conductivity. The reason the range of 0.85 to 1.50 m²/g is more preferred is that the thermal conductivity can be increased by increasing the amount of the flat graphite powder charged and the degree of alignment. As the specific surface area, a value obtained by a BET multipoint method can be used.

The properties of the flat graphite powder can be estimated by a particle size distribution in terms of surface-area frequency. The particle size distribution in terms of surface-area frequency refers to a particle size distribution obtained by performing measurement with a laser diffraction/scattering particle size distribution analyzer using a dry method and then taking statistics about particle size on an area basis.

With respect to the particle size distribution, the flat graphite powder that can be densely charged in the polymer matrix to increase the thermal conductivity has a peak in the range of 20 to 400 μm, and when maximum point P2 of the surface-area frequency in the range of 200 to 400 μm is compared with maximum point P1 of the surface-area frequency in the range of 20 to 150 μm, the ratio P2/P1 is preferably in the range of 0.2 to 2.0. A ratio, P2/P1, of 0.2 to 2.0 indicates that the proportion of the flat graphite powder having a particle size of 200 to 400 μm to the flat graphite powder having a particle size of 20 to 150 μm, which is substantially different therefrom, is within a predetermined range and that the flat graphite powder having a particle size of 200 to 400 μm and the flat graphite powder having a particle size of 20 to 150 μm are contained in predetermined amounts.

A ratio less than 0.2 indicates a high proportion of the flat graphite powder having a particle size of 20 to 150 μm. In this case, the fine particle content is high, making it difficult to densely charge the powder and to increase the thermal conductivity. A ratio more than 2.0 indicates a relatively high proportion of the flat graphite powder having a large particle size, also making it difficult to densely charge the powder and to increase the thermal conductivity.

With respect to the particle size distribution in terms of surface-area frequency, the surface-area frequency at 800 μm or more is preferably 0.1% or less. The flat graphite powder having a particle size of 800 μm or more is highly likely to disturb the alignment. When this flat graphite powder is contained in a proportion more than 0.1% in terms of surface-area frequency, the risk of decreasing the thermal conductivity due to the disturbance of the alignment is increased.

However, if the alignment is not hindered, the proportion of the flat graphite powder having a particle size of 800 μm or more may be more than 0.1%, which is preferred. If the flat graphite powder that has a particle size of 800 μm or more and that is contained in a proportion more than 0.1% can be aligned, the thermal conductivity can be increased.

Thus, if the alignment is improved by, for example, reducing the mixed composition, the proportion of the flat graphite powder having a particle size of 800 μm or more may be contained in a proportion more than 0.1%.

The flat graphite powder content is preferably 75 to 135 parts by mass per 100 parts by mass of the polymer matrix. At a flat graphite powder content less than 75 parts by mass, the thermal conductivity is difficult to increase. A flat graphite powder content more than 135 parts by mass can result in a higher viscosity of the mixed composition to degrade the alignment.

### <Thermally Conductive Filler>

The thermally conductive filler is a material that imparts thermal conductivity to the polymer matrix as well as the flat graphite powder. The thermally conductive filler seems to be interposed between the planes of the aligned flat graphite particles to act as a bridge for conducting heat between the flat graphite particles.

Examples of the thermally conductive filler include spherical or indefinite shaped powders composed of metals, metal oxides, metal nitrides, metal carbides, and metal hydroxides; and spherical graphite. Examples of metals include aluminum, copper, and nickel. Examples of metal oxides include aluminum oxide, magnesium oxide, zinc oxide, and silica. Examples of metal nitrides include boron nitride and aluminum nitride. An example of metal carbides is silicon carbide. An example of metal hydroxides is aluminum hydroxide. Among these thermally conductive fillers, aluminum oxide and aluminum are preferred because they have a high thermal conductivity and because spherical aluminum oxide and spherical aluminum are easily available. Aluminum hydroxide is preferred because it is easily available and can enhance the flame retardancy of the thermally conductive sheet.

The thermally conductive filler preferably has an aspect ratio of 2 or less. At an aspect ratio more than 2, the viscosity is liable to increase to make it difficult to densely charge the thermally conductive filler. For these reasons, the thermally conductive filler preferably has a spherical shape.

The thermally conductive filler preferably has an average particle size of 0.5 to 35 μm. At an average particle size more than 35 μm, the size of the thermally conductive filler is close to the size of the flat graphite powder and thus can disturb the alignment of the flat graphite powder. The thermally conductive filler having an average particle size less than 0.5 μm has a large specific surface area; thus, the viscosity is liable to increase to make it difficult to densely charge the thermally conductive filler. However, when the chargeability is not adversely affected, the thermally conductive filler having an average particle size less than 0.5 μm may be contained. The average particle size of the thermally conductive filler can be expressed as the volume-average particle size in a particle size distribution measured by a laser diffraction/scattering method (JIS R1629).

The thermally conductive filler is preferably added in the range of 250 to 700 parts by mass, more preferably 350 to 600 parts by mass per 100 parts by mass of the polymer matrix. At an amount less than 250 parts by mass, the amount of the thermally conductive filler interposed between the flat graphite particles can be insufficient, thereby degrading the thermal conductivity. At an amount more than 700 parts by mass, the effect of increasing the thermal conductivity is not increased, and, contrarily, the thermal conductivity through the flat graphite powder can be hindered. Within the range of 350 to 600 parts by mass, good thermal conductivity is provided, and an appropriate viscosity of the mixed composition is obtained.

### <Additive>

The uncured polymer matrix may contain various additives to the extent that after the formation, the function of the thermally conductive sheet is not impaired. For example, the uncured polymer matrix may contain organic components, such as a plasticizer, a dispersant, a coupling agent, and an adhesive. A flame retardant, an antioxidant, a curing retarder, a catalyst, and a colorant may also be appropriately added as other components.

### <Mixed Composition>

The uncured polymer matrix, the flat graphite powder, and the thermally conductive filler are mixed together and uniformly dispersed to prepare the mixed composition. Regarding the components contained in the mixed composition, 75 to 135 parts by mass of the flat graphite powder and 250 to 700 parts by mass of the thermally conductive filler are preferably contained per 100 parts by mass of the uncured polymer matrix. When the amounts added are converted into percent by volume, the flat graphite powder corresponds to about 10% to 28% by volume, and the thermally conductive filler corresponds to about 28% to 60% by volume, with respect to about 30% to 50% by volume of the uncured polymer matrix. The mixed composition may appropriately contain foregoing additives.

The viscosity of the mixed composition is preferably, but not necessarily, 10 to 300 Pa·s when magnetic field alignment is performed as described below. A viscosity less than 10 Pa·s can result in settlement of the flat graphite powder and the thermally conductive filler. A viscosity more than 300 Pa·s results in excessively low flowability, thereby failing to align the flat graphite powder by a magnetic field or taking too much time for alignment. When extrusion molding is employed as an alignment method other than the magnetic field alignment, the flat graphite powder can be aligned even at a viscosity more than 300 Pa·s. The mixed composition can have a viscosity less than 10 Pa·s by the use of a thermally conductive filler that is unlikely to settle or in combination with an additive such as an anti-settling agent.

More preferably, the viscosity is 10 to 200 Pa·s. When a large amount of the flat graphite powder having a large particle size is contained, at a viscosity more than 200 Pa·s, it is somewhat difficult to align the flat graphite powder having a large particle size. At a viscosity of 200 Pa·s or less, even the flat graphite powder having a large particle size is easily aligned.

### <Method for Producing Thermally Conductive Sheet>

Among methods for producing the thermally conductive sheet, two methods will be described below.

First, a magnetic field alignment method is described in which the mixed composition is placed in a magnetic field, the flat graphite powder is aligned along the magnetic field, and then the uncured polymer matrix is cured.

The flat graphite powder and the thermally conductive filler are dispersed in the uncured polymer matrix to prepare the mixed composition. Magnetic lines of force are applied to the mixed composition. The mixed composition is formed into a predetermined shape by curing while the particles of the deformed flat graphite powder are aligned in a certain direction, thereby providing the thermally conductive sheet.

Examples of a source of the magnetic lines of force, the source being used to apply the magnetic lines of force, include superconducting magnets, permanent magnets, and coils. A superconducting magnet is preferred because it can generate a magnetic field having a high magnetic flux density. The magnetic flux density of the magnetic field generated from the source is preferably 1 to 30 T. At a magnetic flux density less than 1 T, the deformed flat graphite powder is difficult to align. A magnetic flux density more than 30 T is difficult to achieve practically. Examples of a method for forming the thermally conductive sheet include a bar coating method, a doctor blade method, an extrusion molding method (such as a T-die method), a calendaring method, a press forming method, and a cast molding method.

The thus obtained formed body may be used as a thermally conductive sheet or processed by slicing or cutting into a final shape. Regarding a thermally conductive sheet formed by, for example, casting with a metal mold or a thermally conductive sheet formed by, for example, a bar coating method on a release film, a very thin skin layer composed of a polymer matrix can be formed on a surface of the sheet. The skin layer is effective in suppressing the detachment of the flat graphite powder and the thermally conductive filler. A thermally conductive sheet that does not include the skin layer can also be obtained by performing slicing or cutting along a plane perpendicular to the alignment direction. The thermally conductive sheet that does not include the skin layer has a high thermal conductivity because the flat graphite powder and the thermally conductive filler can come into contact with a heat-generating body or heat-dissipating body in a large area.

Second, a lamination slice method is described in which a shear force is applied to the mixed composition to produce preliminary sheets having a thin plate shape, the preliminary sheets are stacked and cured into a laminated block, and the laminated block is cut into the thermally conductive sheet.

In the lamination slice method, the flat graphite powder, the thermally conductive filler, and if necessary, various additives, are added to the uncured polymer matrix. The mixture is stirred to prepare a mixed composition in which the added solids are uniformly dispersed. The mixed composition preferably has a relatively high viscosity of 10 to 1,000 Pa·s in such a manner that a shear force is applied when the mixed composition is extended.

The mixed composition is flatly extended into a sheet shape while a shear force is applied to the mixed composition. The application of the shear force can align the flat graphite powder in a direction parallel to a flat surface of the sheet. Examples of means for forming a sheet include a method for coating the mixed composition on a base film with an applicator, such as a bar coater or doctor blade, for application or by, for example, extrusion molding or ejection from a nozzle. The thickness of the sheet used here is preferably about 50 to about 250 μm. Thereby, the preliminary sheets can be formed. In the preliminary sheets, the direction of a sheet surface is the same as the alignment direction of the flat graphite powder.

After the preliminary sheets are stacked, the mixed composition is cured into a laminated block by appropriate curing means, such as ultraviolet irradiation or pressing under heat, for curing the uncured polymer matrix. The laminated block is cut in a direction orthogonal to the alignment direction of the flat graphite powder to produce a thermally conductive sheet having a sheet-like shape.

The first magnetic field alignment method is compared with the second lamination slice method.

In the lamination slice method, it is difficult to produce a soft thin thermally conductive sheet. For example, in the case of an E hardness of about 20 or less, even if a blade that is as sharp as possible is used, the sheet is markedly deformed by a pressing force applied during slicing because the sheet is too soft. It is thus difficult to obtain a high-quality thin sheet. As a countermeasure against this problem, a method is exemplified in which the laminated block is frozen and sliced. The freezing method is effective for an acrylic gel. However, in the thermally conductive sheet containing the silicone polymer matrix, the quality of a slice is not improved because even if the laminated block is frozen at −40°, the hardness is substantially unchanged. If the laminated block is further cooled to a lower temperature (practically, to about)−60°, the laminated block can be hardened to improve the quality of a slice; however, a special apparatus is required to cool the laminated block to a temperature lower than −40°, and cooling is inhibited by frictional heat during slicing. Thus, this process cannot be practically employed.

To achieve a reliable contact of adherends and reduce the thermal resistance, the thermally conductive sheet is generally used while being compressed by about 10% to about 40%. A softer sheet results in a smaller stress due to compression, thus leading to a low risk of distorting a substrate serving as an adherend by stress. However, because the hardness is limited in the lamination slice method, it is difficult to obtain a very soft thermally conductive sheet.

The lamination slice method also has the following problems: Anisotropy occurs in terms of physical properties and the thermal conductivity in the plane direction of the thermally conductive sheet. The degraded adhesion of the surfaces makes it difficult to fix the sheet to the adherends, thus leading to poor workability. The stacking and bonding steps and the slicing step are performed, causing an increase in cost. Furthermore, when the thermally conductive sheet is arranged between a heat-generating body and a heat-dissipating body, a pressing force is applied in a direction in which the bonded surface of the sheets collapses. This can cause delamination at the bonded surface and the detachment of the particles of the flat graphite powder.

In contrast, in the magnetic field alignment method, the directions of normals to the flat surfaces of the particles of the flat graphite powder extend parallel to a flat surface of the thermally conductive sheet, and the flat surfaces face randomly. In the lamination slice method, the directions of normals to the flat surfaces of the particles of the flat graphite powder extend parallel to a flat surface of the thermally conductive sheet, and the flat surfaces are arranged in parallel. With regard to the alignment of the flat graphite powder by the magnetic field alignment method, because the flat surfaces of the particles of the flat graphite overlap one another or do not overlap one another, the flat surfaces of the particles of the flat graphite are unlikely to be detached. This results in isotropic heat conduction in the plane direction of the sheet. Furthermore, because the thermally conductive sheet does not include a bonded surface of bonded sheets, a problem of delamination at the bonded surface does not arise. Accordingly, for the foregoing reasons, the production by the magnetic field alignment method is preferred.

### <Properties of Thermally Conductive Sheet>

The thermally conductive sheet preferably has a hardness of 0 to 95, more preferably 0 to 60, the hardness being measured with a type E durometer specified in JIS K 6253 of the Japanese Industrial Standards (hereinafter, referred to as “E hardness”). An E hardness more than 95 does not result in sufficient conformability to the shapes of a heat-generating body and a heat-dissipating body. This can reduce the adhesion of the thermally conductive sheet to the heat-generating body and the heat-dissipating body to reduce the thermal conductivity. An E hardness of 95 or less results in good conformability of the thermally conductive sheet to the shapes of the heat-generating body and the heat-dissipating body to obtain sufficiently high adhesion of the thermally conductive sheet to the heat-generating body and the heat-dissipating body. An E hardness of 60 or less results in only a low stress due to compression even at a high compressibility when the thermally conductive sheet is arranged between the heat-generating body and the heat-dissipating body.

The lower limit of hardness of the thermally conductive sheet is zero in terms of E hardness. In this case, the lower limit is preferably 5 or more, more preferably 10 to 80 in terms of type OO durometer hardness (hereinafter, referred to as “OO hardness”) specified in ASTM D2240 of the American Society of Testing Materials. At an OO hardness of 5 or more, the thermally conductive sheet can have physical properties to the extent that its shape is maintained even at an E hardness of 0. At an OO hardness ranging from 10 to 80, the thermally conductive sheet can have handleability to a certain extent, and a stress due to compression can be very low.

The thermally conductive sheet may have a predetermined tackiness (adherence). A value of the coefficient of static friction can be an index of the tackiness. The value of the coefficient of static friction is preferably about 8.0 to about 20.0, more preferably 10.0 to 15.0. At a value of the coefficient of static friction ranging from 8.0 to 20.0, the thermally conductive sheet is easily fixed to a heat-generating body and a heat-dissipating body and has good workability for mounting. A value of the coefficient of static friction ranging from 10.0 to 15.0 results in particularly good fixability and workability. The coefficient of static friction can be measured by a method described in an experimental example below.

The thermally conductive sheet may have a thermal conductivity of 12 to 30 W/m·K. This thermal conductivity is a thermal conductivity in the thickness direction of the sheet and can be calculated using a method described in an experimental example below. When “thermal conductivity” is simply stated in the present invention, the thermal conductivity indicates a thermal conductivity in the thickness direction of the sheet, unless otherwise specified.

The flat surfaces of the particles of the flat graphite powder in the thermally conductive sheet are aligned in the thickness direction of the sheet. More specifically, the percentage of the number of the flat graphite powder particles whose flat surfaces have an angle less than 30° to the thickness direction of the sheet is more than 50%. Because the flat graphite powder and the thermally conductive filler having a small aspect ratio are contained in appropriate proportions in this alignment state, the thermally conductive filler is appropriately interposed in gaps between the surfaces of the particles of the flat graphite powder, thereby providing the thermally conductive sheet having a high thermal conductivity.

The thermally conductive sheet of the present invention contains the thermally conductive filler together with the flat graphite powder and has a relatively low graphite content, a good flexibility, and a good tackiness on the surfaces of the sheet. Thus, even if the thermally conductive sheet is interposed and compressed between a heat-generating body and a heat-dissipating body, a compressive stress is low. This reduces the risk of distorting a substrate and applying an excessive pressure. Furthermore, the thermally conductive sheet is easily fixed to a heat-generating body and a heat-dissipating body and has good workability.

### EXAMPLES

The present invention will be described in more detail by specific examples.

### <Production of Flat Graphite Powder>

A polyimide film having a thickness of 25 μm was heat-treated at 2,600° C. for 4 hours in an argon gas atmosphere to provide a graphite film having a thickness of about 17 μm. The resulting graphite film was pulverized with a pin mill. At this time, flat graphite powders 1 to 4 having different particle sizes were produced by changing the number of revolutions of the pin mill and the treatment time. Specifically, flat graphite powder 4 having a large particle size was produced at a small number of revolutions and a short treatment time. Then flat graphite powder 3 was produced at a larger number of revolutions and a longer pulverization time. Next, flat graphite powder 2 was produced at a larger number of revolutions and a longer pulverization time than those for graphite powder 3. Finally, graphite powder 1 was produced at a larger number of revolutions and a longer pulverization time than those for graphite powder 2.

### (Particle Size Distribution of Flat Graphite Powder)

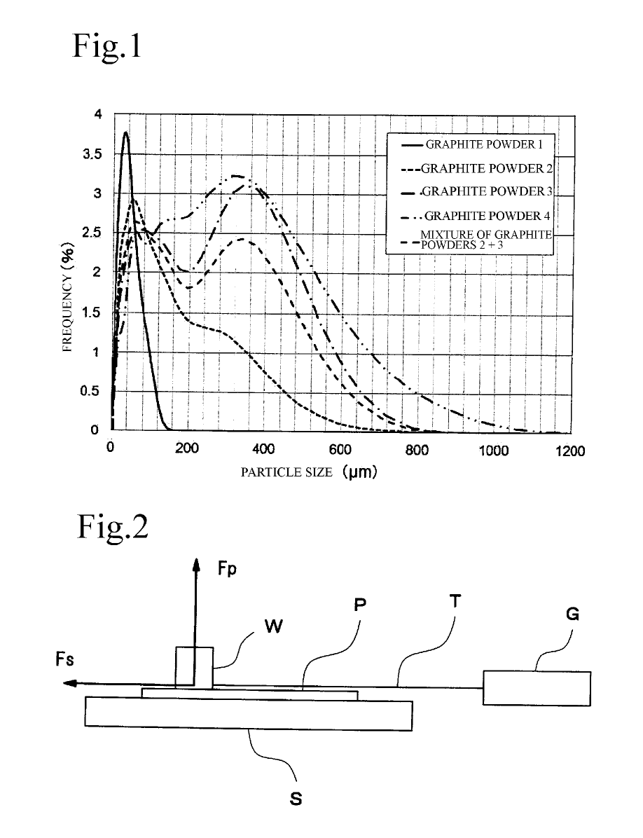

The particle size distributions of flat graphite powders 1 to 4 were measured with an LS230 laser diffraction/scattering particle size distribution analyzer (manufactured by Beckman Coulter, Inc). At this time, a dry powder module was used. A vibrator and an auger were adjusted so as to achieve a dry powder concentration of 3% to 5%. The measurement time was set to 60 seconds. Fraunhofer was selected as an optical model. The frequency was calculated on an area basis (surface-area frequency). FIG. 1 illustrates a particle size distribution determined as described above.

Observations of flat graphite powders 1 to 4 using an electron microscope indicated the following: Flat graphite powder 1 contained the highest proportion of scale-like particles having a size of about 35 μm. Flat graphite powder 2 contained the highest proportion of scale-like particles having a size of about 80 μm and also contained a high proportion of scale-like particles having a size up to about 300 μm. Flat graphite powder 3 contained the highest proportion of scale-like particles having a size of about 300 to about 400 μm. Flat graphite powder 4 contained a high proportion of scale-like particles having a size of about 100 to about 400 μm and also contained a small proportion of scale-like particles having a large size of 800 μm or more.

### (Specific Surface Area of Flat Graphite Powder)

The specific surface areas of flat graphite powders 1 to 4 were measured by a BET multipoint method with a Gemini automated specific surface area measurement instrument (manufactured by Shimadzu Corporation). The specific surface areas of flat graphite powders 1 to 4 were 2.33 m²/g, 1.27 m²/g, 0.91 m²/g, and 0.83 m²/g, respectively.

### (Aspect Ratio of Flat Graphite Powder)

Observations on the shape of flat graphite powders 1 to 4 indicated that many flat particles having a long-axis length of 35 to 400 μm were observed in each of flat graphite powders 1 to 4. The particles of the flat graphite powders had a thickness of about 17 μm and thus an aspect ratio of about 2 to about 24.

### <Preparation of Mixed Composition and Formation of Thermally Conductive Sheet>

Each of the flat graphite powders, a thermally conductive filler, and an uncured polymer matrix were mixed together to prepare mixed compositions and thermally conductive sheets of samples 1 to 20 described in detail below.

### Sample 1

Flat graphite powder 2 (specific gravity: 2.2), spherical aluminum oxide (specific gravity: 4.0) serving as thermally conductive filler 1 having a particle size of 3 μm and an aspect ratio of about 1, and spherical aluminum oxide (specific gravity: 4.0) serving as thermally conductive filler 2 having a particle size of 10 μm and an aspect ratio of about 1 were mixed with a mixture (specific gravity: 1.0) of an alkenyl group-containing polyorganosiloxane and an organohydrogenpolysiloxane, which were addition reaction-type silicones, serving as the uncured polymer matrix, in proportions listed in Table 1. After the resulting composition was stirred so as to uniformize the composition, the composition was defoamed to prepare a mixed composition of sample 1. Flat graphite powder 1 and thermally conductive fillers 1 and 2 were subjected to surface treatment with a silane-coupling agent before use.

The mixed composition was formed by metal molding into a sheet. The sheet was placed in a magnetic field of 8 T, generated by a superconducting magnet, for 10 minutes in such a manner that magnetic lines of force was applied to the sheet in the thickness direction of the sheet. The sheet was heated at 120° C. for 30 minutes to provide a 2.0-mm-thick thermally conductive sheet of sample 1. The composition of sample 1 is listed in Table 1.

### Samples 2 to 22

Mixed compositions of samples 2 to 22 were prepared in the same way as in sample 1, except that the composition of sample 1 was changed as listed in Tables 1 to 3. Thermally conductive sheets of samples other than samples 10, 14, or 17 were produced in the same way as the method for producing the thermally conductive sheet of sample 1. The compositions and properties of samples 2 to 22 were listed in Tables 1 to 3. Flat graphite powders 2 to 4 and thermally conductive fillers 3 and 4 were also subjected to surface treatment with a silane-coupling agent before use.

TABLE 1

| | | Sample | Sample | Sample | Sample | Sample | Sample | Sample | Sample |
|---|---|---|---|---|---|---|---|---|---|
| | | 1 | 2 | 3 | 4 | 5 | 6 | 7 | 8 |
| Component | Polymer matrix | 100 | 100 | 100 | 100 | 100 | 100 | 100 | 100 |
| mixed (parts | Flat graphite powder 1 | — | 90 | — | — | — | — | — | — |
| by mass) | Flat graphite powder 2 | 90 | — | 30 | — | — | — | — | — |
| | Flat graphite powder 3 | — | — | 60 | 90 | — | — | 90 | 90 |
| | Flat graphite powder 4 | — | — | — | — | 90 | — | — | — |
| | Graphitized carbon fiber | — | — | — | — | — | 90 | — | — |
| | Thermally conductive filler 1 | 250 | 250 | 250 | 250 | 250 | 250 | 250 | 250 |
| | Thermally conductive filler 2 | 200 | 200 | 200 | 200 | 200 | 200 | — | — |
| | Thermally conductive filler 3 | — | — | — | — | — | — | 200 | — |
| | Thermally conductive filler 4 | — | — | — | — | — | — | — | 200 |
| Mixing ratio | Polymer matrix | 39.5 | 39.5 | 39.5 | 39.5 | 39.5 | 39.5 | 39.5 | 39.5 |
| (% by | Graphites | 16.1 | 16.1 | 16.1 | 16.1 | 16.1 | 16.1 | 16.1 | 16.1 |
| volume) | Thermally conductive filler | 44.4 | 44.4 | 44.4 | 44.4 | 44.4 | 44.4 | 44.4 | 44.4 |
| Properties | Viscosity (Pa · s) | 178 | — | 135 | 189 | 250 | 48 | 185 | 162 |
| | Thermal conductivity | 14.1 | 7.4 | 14.1 | 13.8 | 11.0 | 10.8 | 15.1 | 10.4 |
| | Evaluation | ⊙ | X | ⊙ | ⊙ | ◯ | ◯ | ⊙ | ◯ |
| | OO hardness | 58 | 71 | 48 | 58 | 61 | 60 | 60 | 68 |

TABLE 2

| | | Sample | Sample | Sample | Sample | Sample | Sample | Sample | Sample | Sample | Sample |
|---|---|---|---|---|---|---|---|---|---|---|---|
| | | 9 | 10 | 11 | 12 | 13 | 14 | 15 | 16 | 17 | 18 |
| Component | Polymer matrix | 100 | 100 | 100 | 100 | 100 | 100 | 100 | 100 | 100 | 100 |
| mixed (parts | Flat graphite powder 1 | — | — | — | — | — | — | — | — | — | — |
| by mass) | Flat graphite powder 2 | — | — | 35 | 30 | 45 | 50 | 30 | — | — | — |
| | Flat graphite powder 3 | — | 90 | 70 | 60 | 90 | 100 | 60 | 75 | 75 | — |
| | Flat graphite powder 4 | — | — | — | — | — | — | — | — | — | 75 |
| | Graphitized carbon fiber | — | — | — | — | — | — | — | — | — | — |
| | Thermally conductive filler 1 | 340 | — | 250 | 250 | 250 | 250 | 150 | 700 | 850 | 250 |
| | Thermally conductive filler 2 | 200 | — | — | — | — | — | — | — | — | 200 |
| | Thermally conductive filler 3 | — | — | — | — | — | — | — | — | — | — |
| | Thermally conductive filler 4 | — | — | — | — | — | — | — | — | — | — |
| Mixing ratio | Polymer matrix | 42.6 | 71.0 | 47.6 | 49.2 | 44.7 | 43.3 | 56.1 | 32.4 | 28.9 | 40.6 |
| (% by | Graphites | 0.0 | 29.0 | 22.7 | 20.1 | 27.4 | 29.6 | 22.9 | 11.0 | 9.8 | 13.8 |
| volume) | Thermally conductive filler | 57.4 | 0.0 | 29.7 | 30.7 | 27.9 | 27.1 | 21.0 | 56.6 | 61.3 | 45.6 |
| Properties | Viscosity (Pa · s) | 18 | — | 190 | 137 | 298 | — | 125 | 256 | — | 178 |
| | Thermal conductivity | 3.0 | — | 13.0 | 11.4 | 18.5 | — | 11.0 | 13.5 | — | 12.8 |
| | Evaluation | X | X | ⊙ | ⊙ | ⊙ | X | ◯ | ⊙ | X | ⊙ |
| | OO hardness | 49 | — | 61 | 58 | 72 | — | 64 | 76 | — | 52 |

TABLE 3

| | | Sample 19 | Sample 20 | Sample 21 | Sample 22 |
|---|---|---|---|---|---|
| Component | Polymer matrix | modification 1 | modification 2 | the same as | the same as |
| mixed | Flat graphite powder 1 | of sample 3 | of sample 3 | in sample 6 | in sample 3 |
| (parts by | Flat graphite powder 2 | | | | |
| mass) | Flat graphite powder 3 | | | | |
| | Flat graphite powder 4 | | | | |
| | Graphitized carbon fiber | | | | |
| | Thermally conductive filler 1 | | | | |
| | Thermally conductive filler 2 | | | | |
| | Thermally conductive filler 3 | | | | |
| | Thermally conductive filler 4 | | | | |
| Mixing ratio | Polymer matrix | | | | |
| (% by | Graphites | | | | |
| volume) | Thermally conductive filler | | | | |
| Properties | Viscosity (Pa · s) | | | | |
| | Thermal conductivity | | | | |
| | Evaluation | | | | |
| | E hardness | E50 | E60 | | |
| | Remarks | amount of | amount of | ½ of | adhesive on |
| | | curing agent | curing agent | thickness of | surface |
| | | in polymer | in polymer | sample 6 | |
| | | matrix: | matrix: further | | |
| | | increased | increased | | |

The following materials were used as materials listed in Tables 1 to 3.

“Carbon fiber” represents graphitized carbon fibers that had an average fiber length of 100 μm and an average diameter of 10 μm and that produced from pitch. “Thermally conductive filler 1” represents spherical aluminum oxide having an average particle size of 3 μm. “Thermally conductive filler 2” represents spherical aluminum oxide having an average particle size of 10 μm. “Thermally conductive filler 3” represents spherical aluminum oxide having an average particle size of 35 μm. “Thermally conductive filler 4” represents spherical aluminum oxide having an average particle size of 50 μm. The average particle sizes of the thermally conductive fillers 1 to 4 represent volume-average particle sizes in particle size distributions measured by a laser diffraction/scattering method (JIS R1629). The aspect ratios of thermally conductive fillers 1 to 4 were observed using an electron microscope and found to be about 1.0.

### <Properties of Mixed Composition and Thermally Conductive Sheet>

### (Measurement of Viscosity)

The viscosity of the mixed composition for each of the samples was measured with a rotational viscometer (trade name: Model DV-E, spindle No. 14, manufactured by Brookfield) in an atmosphere at 25° C. and 10 rpm. Tables 1 to 3 also list the results. Samples that could not be measured are expressed as “-” in the tables. All of the samples that could not be measured were more viscous than those of the samples that could be measured and empirically seemed to have a viscosity more than 300 Pa·s.

### (Measurement of Hardness)

Three thermally conductive sheets of each sample were stacked to form a test piece having a thickness of 6 mm. The OO hardness of the test piece was measured with a type OO durometer. Tables 1 to 3 also list the results.

### (Measurement of Thermal Resistance Value and Thermal Conductivity)

The thermally conductive sheets were cut into 10 mm×10 mm square test pieces. Each of the test pieces was interposed between a heat-generating substrate (amount of heat generated Q: 25 W) and a heat sink (FH60-30, manufactured by Alpha Co., Ltd.), and a certain load (2 kgf/cm²) was applied to the heat sink. A cooling fan (airflow rate: 0.01 kg/sec, fan pressure: 49 Pa) was attached to an upper portion of the heat sink. The heat sink and the heat-generating substrate were connected to temperature sensors. The heat-generating substrate is energized while the cooling fan was operated. After a lapse of 5 minutes from the start of the energization, the temperature (T1) of the heat-generating substrate and the temperature (T2) of the heat sink were measured. The thermal resistance value of the test piece of each sample was calculated by substituting the temperatures for variables in expression (1).

Thermal resistance value (° C./W)=(T1−T2)/amount of heat generated Q (1)

The thermal resistance value was converted into thermal conductivity using relational expression (2). The tables list the results. In the tables, the thermal conductivity was rated as follows: a preferred thermal conductivity is expressed as “⊙”, a somewhat preferred thermal conductivity is expressed as “◯”, and an inappropriate thermal conductivity is expressed as “×”.

Thermal resistance value (° C./W)=thickness in heat transfer direction (m)/(heat transfer sectional area (m²)×thermal conductivity (W/m·K)) (2)

### (Measurement of Coefficient of Static Friction)

The coefficient of static friction was used as an index of the tackiness of the thermally conductive sheet of each sample. The coefficient of static friction can be measured with an experimental apparatus illustrated in FIG. 2. A test piece (P) (150 mm×150 mm square) of the thermally conductive sheet was placed on a horizontal stage (S) that was composed of stainless steel and that had a mirror-finished surface. On the test piece (P), a 147-g weight (W) (circular cylinder having a diameter of 50 mm, stainless steel, mirror-finished contact surface) was placed. An end of a tape (T) to pull the weight (W) was attached near the lower end of the weight (W). The other end of the tape (T) was fixed to a push-pull gauge (G) (cylindrical tension gauge 4000, manufactured by Oba gauge manufacturing Co., Ltd). The test piece (P) was pulled in the lateral direction of the test piece (P) at a rate of 100 mm/min. The static friction force Fs (N) between the test piece (P) and the weight (W) was measured when the push-pull gauge (G) was pulled. More specifically, the coefficient of static friction was calculated from expression (3) using the weight of the weight (W) and the traction when the test piece (P) was pulled. For the thermally conductive sheet of each test piece (P), the measurement of the static friction force Fs and the calculation of the coefficient of static friction were performed 5 times. The average value thereof was defined as the coefficient of static friction of the thermally conductive sheet.

Coefficient of static friction=Fs(N)/Fp(N) (3)

In expression (3), Fp represents a normal force generated by the mass (weight) of the weight. The value of Fp is expressed as 0.147 kg (weight of the weight)×9.8 m/s² (acceleration of gravity)=1.4406 N.

### <Evaluation of Sample>

The mixed composition of sample 1 had a viscosity of 178 Pa·s. The thermally conductive sheet had a thermal conductivity of 14.1 W/m·K and an OO hardness of 58. Although the viscosity was somewhat high, the mixed composition was uniformly mixed. Observations of a cross section of the thermally conductive sheet using an electron microscope indicated that the flat graphite powder was regularly aligned.

The viscosity of the mixed composition of sample 2 was too high to measure the viscosity. Although the mixed composition was barely formed into a sheet shape, the workability was poor. Observations of a cross section of the thermally conductive sheet of sample 2 using a microscope indicated that the surfaces of the particles of the flat graphite powder were not aligned in the thickness direction of the sheet. The surfaces of the particles of the flat graphite powder face randomly in various directions when observed from a sheet surface. The thermally conductive sheet of sample 2 had a low thermal conductivity of 7.4 W/m·K and an OO hardness of 71.

The mixed composition of sample 3 had a viscosity of 135 Pa·s. The thermally conductive sheet had a thermal conductivity of 14.1 W/m·K and an OO hardness of 48. Observations of a cross section of the thermally conductive sheet indicated that the flat graphite powder was regularly aligned.

The mixed composition of sample 4 had a viscosity of 189 Pa·s. The thermally conductive sheet had a thermal conductivity of 13.8 W/m·K and an OO hardness of 58. Although the mixed composition had a somewhat high viscosity, observations of a cross section of the thermally conductive sheet using an electron microscope indicated that the flat graphite powder was regularly aligned.

The mixed composition of sample 5 had a viscosity of 250 Pa·s. The thermally conductive sheet had a somewhat low thermal conductivity of 11.0 W/m·K and an OO hardness of 61. Observations of a cross section of the thermally conductive sheet using an electron microscope indicated that although many particles of the flat graphite powder were aligned, some flat graphite powder particles having a size of 600 μm or more were not completely aligned and were obliquely arranged, thereby seemingly resulting in a slight reduction in thermal conductivity.

In sample 6, the flat graphite powder was replaced with carbon fibers. The mixed composition of sample 6 had a viscosity of 48 Pa·s. The thermally conductive sheet had a thermal conductivity of 10.8 W/m·K and an OO hardness of 60. Observations of a cross section of the thermally conductive sheet using an electron microscope indicated that the flat graphite powder was regularly aligned.

In sample 7, aluminum oxide having a somewhat large average particle size of 35 μm was used as a thermally conductive filler. The mixed composition of sample 7 had a viscosity of 185 Pa·s. The thermally conductive sheet had a high thermal conductivity of 15.1 W/m·K and an OO hardness of 60. Observations of a cross section of the thermally conductive sheet using an electron microscope indicated that the flat graphite powder was regularly aligned. The reason for the somewhat high thermal conductivity is presumably that the large particle size of the aluminum oxide interposed between the graphite powder particles promoted heat conduction.

In sample 8, aluminum oxide having a large average particle size of 50 μm was used as a thermally conductive filler. The mixed composition of sample 8 had a viscosity of 162 Pa·s. The thermally conductive sheet had a low thermal conductivity of 10.4 W/m·K and an OO hardness of 68. Observations of a cross section of the thermally conductive sheet using an electron microscope indicated that some particles of the flat graphite powder were fixed along the outlines of aluminum oxide particles having a large particle size. The state seemingly indicated that the aluminum oxide having a large particle size hindered the alignment of the flat graphite powder. The reason for the somewhat low thermal conductivity is presumably the disturbance of the alignment.

Sample 9 did not contain a flat graphite powder. The mixed composition of sample 9 had a viscosity of 18 Pa·s. In the thermally conductive sheet, the components were not uniformly dispersed. The thermally conductive sheet had a very low thermal conductivity of 3.0 W/m·K and an OO hardness of 49.

Sample 10 did not contain a thermally conductive filler. With regard to the mixed composition of sample 10, the flat graphite powder was not uniformly dispersed in the uncured polymer matrix to fail to prepare a flowable composition. Thus, the mixed composition could not be formed into a sheet shape, thereby failing to produce a thermally conductive sheet.

In sample 11, the amount of aluminum oxide was reduced, and the amount of the flat graphite powder was increased. The mixed composition of sample 11 had a viscosity of 190 Pa·s. The thermally conductive sheet had a thermal conductivity of 13.0 W/m·K and an OO hardness of 61.

The mixed composition of sample 12 had a viscosity of 137 Pa·s. The thermally conductive sheet had a thermal conductivity of 11.4 W/m·K and an OO hardness of 58.

In sample 13, the amount of the flat graphite powder was further increased. The mixed composition of sample 13 had a viscosity of 298 Pa·s. The thermally conductive sheet had a thermal conductivity of 18.5 W/m·K and an OO hardness of 72.

In sample 14, the amount of the flat graphite powder was larger than that in sample 13. In sample 14, the flat graphite powder was not uniformly dispersed in the uncured polymer matrix to fail to prepare a flowable uniform composition. Thus, the composition could not be formed into a sheet shape, thereby failing to produce a thermally conductive sheet.

In sample 15, the amount of the thermally conductive filler was relatively small. The mixed composition of sample 15 had a viscosity of 125 Pa·s. The thermally conductive sheet had a somewhat low thermal conductivity of 11.0 W/m·K and an OO hardness of 64.

In sample 16, the amount of the thermally conductive filler was relatively increased. The mixed composition of sample 16 had a viscosity of 256 Pa·s. The thermally conductive sheet had a thermal conductivity of 13.5 W/m·K and an OO hardness of 76.

In sample 17, the amount of the thermally conductive filler was further increased. In sample 17, the flat graphite powder was not uniformly dispersed in the uncured polymer matrix to fail to prepare a flowable uniform composition. Thus, the composition could not be formed into a sheet shape, thereby failing to produce a thermally conductive sheet.

In sample 18, the amount of the flat graphite powder was smaller than that in sample 5. The mixed composition of sample 18 had a viscosity of 178 Pa·s. The thermally conductive sheet had a thermal conductivity of 12.8 W/m·K and an OO hardness of 52.

In sample 19, although the same types and amounts of the flat graphite powder and the thermally conductive filler as those in sample 3 were used, the percentage of the curing agent with respect to the main component in 100 parts by mass of the polymer matrix was increased. The tackiness of a sheet surface of the thermally conductive sheet of sample 19 was reduced by the increase in the percentage of the curing agent. The hardness was E50.

In sample 20, although the same types and amounts of the flat graphite powder and the thermally conductive filler as those in sample 3 were used, the percentage of the curing agent with respect to the main component in 100 parts by mass of the polymer matrix was higher than that in sample 19. The tackiness of a sheet surface of the thermally conductive sheet of sample 20 was reduced by the further increase in the percentage of the curing agent. The hardness was E60.

Sample 21 was a thermally conductive sheet produced by slicing the 2-mm-thick thermally conductive sheet of sample 6 into a thickness of 1 mm (half). The coefficient of static friction was measured on the slice surface.

Sample 22 was a thermally conductive sheet produced by applying an adhesive to a sheet surface of the thermally conductive sheet of sample 3 to increase the tackiness.

### <Discussion>

### (Effect of Flat Graphite Powder)

A comparison of thermally conductive sheets of samples 1 to 5 indicated the following: Sample 2 containing flat graphite powder 1 had a low thermal conductivity of 7.4 W/m·K. Sample 5 containing flat graphite powder 4 had a somewhat low thermal conductivity of 11.0 W/m·K. In contrast, samples 1, 3, and 4 had a high thermal conductivity of 13.8 W/m·K to 14.1 W/m·K. The results indicate that flat graphite powder 4 is more preferable than flat graphite powder 1 and that flat graphite powders 2 and 3 are more preferable than flat graphite powder 4. The thermally conductive sheet containing flat graphite powder 2 has a thermal conductivity comparable to the thermally conductive sheet containing flat graphite powder 3.

In sample 2, the flat surfaces of the particles of the flat graphite powder 1 are not aligned in the thickness direction of the sheet. The disturbance of the alignment seemingly causes the low thermal conductivity. The main reason for the disturbance of the alignment is presumably that the flat graphite powder used had a somewhat large specific surface area of 2.33 m²/g and thus had a high viscosity. This can also be interpreted from FIG. 1 which illustrates a particle size distribution. Specifically, in flat graphite powder 1, the percentage of the particles having a size of about 30 μm is high, and substantially no particles having a size of 200 μm or more is contained; thus, the specific surface area is seemingly large. In contrast, flat graphite powders 2 to 4 have a specific surface area of 1.27 to 0.83 m²/g; thus, unlike flat graphite powder 1, the viscosity was not so increased.

A comparison of the viscosity of samples 1, 3, and 4 indicated that sample 3 had a lower viscosity. When the viscosity is low, the amounts of the flat graphite powder and the thermally conductive filler charged can be increased until the viscosity reaches a predetermined value. There is a room for improvement in terms of thermal conductivity. For this reason, flat graphite powders 2 and 3 are preferably used in combination rather than separately.

These differences will be discussed below on the basis of the particle size distribution in FIG. 1. Flat graphite powder 2 has a peak at about a particle size of 60 μm. Flat graphite powder 3 has a small peak at about 60 μm and a large peak at about 370 μm. In the powder mixture used in sample 3, the height of a peak at about 60 μm is comparable to that of a peak at about 370 μm. From the results, when the graphite particles in the two peak bands have the same frequency, the minimum viscosity is seemingly obtained.

The two peak bands were defined as 20 to 150 μm and 200 to 400 μm. The maximum frequency point P1 in the range of 20 to 150 μm and the maximum frequency point P2 in the range of 200 to 400 μm were estimated, and the value of P2/P1 was calculated. The value was “0” for flat graphite powder 1, “0.48” for flat graphite powder 2, “1.23” for flat graphite powder 3, 1.29 for flat graphite powder 4, and “0.92” for the mixture of flat graphite powders 2 and 3 mixed in a ratio of 1:2. From these results, the value of P2/P1 of flat graphite powder 2, flat graphite powder 3, the mixture thereof, or flat graphite powder 4 to be added is preferably in the range of 0.2 to 2.0, more preferably 0.48 to 1.29. Among these, the value of P2/P1 of flat graphite powder 2, flat graphite powder 3, or the mixture thereof to be added is most preferably in the range of 0.48 to 1.23.

A comparison of samples 1, 3, 4, and 5 indicated that sample 5 had a somewhat low thermal conductivity. Observations of the cross section of sample 5 using the electron microscope indicated that in particular, large particles of the flat graphite powder having a particle size more than 800 μm were not aligned in a direction perpendicular to the sheet surface. This demonstrates that large flat graphite powder particles are difficult to align. In consideration of this, let us now look at the particle size distribution of FIG. 1. Flat graphite powder 4 contains a higher proportion of flat graphite powder particles having a size of 800 μm or more than other flat graphite powders. The frequency thereof was 0.5% for flat graphite powder 4. The frequency thereof was less than 0.1% for flat graphite powder 3, which contained the next largest proportion thereof. Thus, the surface-area frequency at 800 μm or more is preferably 0.1% or less.

A comparison of samples 5 and 18 indicated that sample 18, which contained a lower flat graphite powder content, had a slightly higher thermal conductivity. Both samples contained, in terms of a flat graphite powder, flat graphite powder 4 alone. Nevertheless, observations of sample 5 indicated that the large particles of the flat graphite powder were not aligned, whereas observations of a cross section of sample 18 using an electron microscope indicated that large flat graphite powder particles having a size more than 800 μm were aligned in a direction perpendicular to a sheet surface. The difference in the degree of alignment of the large particles of the flat graphite powder seems to result in the fact that despite the lower flat graphite powder 4 content of sample 18, sample 18 had a higher thermal conductivity than sample 5.

The reason for the large particles of the flat graphite powder in sample 18 were aligned is presumably that the mixed composition of sample 5 had a high viscosity of 250 Pa·s, whereas the mixed composition of sample 18 had a low viscosity of 178 Pa·s. That is, even slightly large flat graphite powder particles can be aligned as long as the viscosity is 200 Pa·s or less.

A comparison of samples 4 and 6 indicates that when equal amounts (parts by mass) of the flat graphite powder and the carbon fibers are added, the addition of the flat graphite powder achieves a higher thermal conductivity than that in the case of the addition of the carbon fibers.

### (Effect of Thermally Conductive Filler)

A comparison is made of samples 4, 9, and 10. Like sample 9, when no flat graphite powder is contained, the thermal conductivity is significantly low. In contrast, like sample 10, when no thermally conductive filler is contained, the flat graphite powder is difficult to disperse, thus failing to prepare a mixed composition. The results indicate that the addition of a predetermined thermally conductive filler to the flat graphite powder increases the thermal conductivity and is also effective in increasing the dispersibility of the flat graphite powder.

A comparison analysis is made of samples 3, 10, 12, 15, 16, and 17 on the amounts of the thermally conductive filler added. In sample 10, which contained no thermally conductive filler, uniform dispersion could not be performed. Although the thermally conductive sheet of sample 15, which contained 150 parts by mass of the thermally conductive filler, had a slightly low thermal conductivity of 11.0 W/m·K, the mixed composition had a very low viscosity of 125 Pa·s. The thermally conductive sheet of sample 12, which contained 250 parts by mass of the thermally conductive filler, had a thermal conductivity of 11.4 W/m·K. The mixed composition had a viscosity of 137 Pa·s. Despite the not so high viscosity, the thermal conductivity was high. In sample 3, which contained 450 parts by mass of the thermally conductive filler, the viscosity was 135 Pa·s. The thermal conductivity was successfully increased to 14.1 W/m·K without increasing the viscosity. These results indicate that the thermally conductive filler is preferably added in an amount of at least 150 parts by mass, more preferably 250 parts by mass or more.

Sample 16, which contained a slightly smaller amount of the flat graphite powder and 700 parts by mass of the thermally conductive filler, had a thermal conductivity of 13.5 W/m·K, the viscosity was 256 Pa·s. The increase in the amount of the thermally conductive filler added to 700 parts by mass markedly increased the viscosity to fail to increase the amount added to 850 parts by mass. Thus, the amount of the thermally conductive filler added is preferably up to about 700 parts by mass.

The resulting values are converted in terms of volume fractions. The flat graphite powder is preferably contained in an amount of about 10% to about 28% by mass. The thermally conductive filler is preferably contained in an amount of about 20% to about 60% by mass.

### (Combination of Flat Graphite Powder and Thermally Conductive Filler)

The ratio of the flat graphite powder to the thermally conductive filler is analyzed on a volume basis. The values of “graphite (% by volume)/thermally conductive filler (% by volume)” are calculated from the mixing ratios listed in Tables 1 to 3 and found to be “0.16” for sample 17, “0.19” for sample 16, “0.36” for sample 4, “0.76” for sample 11, “0.98” for sample 13, and “1.09” for sample 15. Among these, in sample 17, a thermally conductive sheet was not produced because of poor dispersibility. At the ratio in sample 16, a predetermined thermally conductive sheet could be produced. Thus, the lower limit is about 0.19. Sample 15 had a somewhat low thermal conductivity. Sample 13 had a good thermal conductivity. Thus, the upper limit seems to be about 1.0.

### (Tackiness)

The thermally conductive sheets of samples 3, 6, and 9 that had type OO hardnesses of 48 to 60 had coefficients of static friction of 10.9 to 12.2. In contrast, in the thermally conductive sheets of samples 19 and 20, which had increased hardness, sample 19 having a hardness of E60 had a coefficient of static friction of 8.2, and sample 20 having a hardness of E70 had a coefficient of static friction of 2.0. With regard to the slice surface obtained by slicing sample 6, sample 21 had a reduced coefficient of static friction of 0.3. Sample 22 having a surface to which the adhesive was applied had an increased coefficient of static friction of 27.2.

The test results indicate the following: Sample 21 had no tackiness and had good sliding properties. Sample 20 had a coefficient of static friction of 2.0 but had a low degree of tackiness. Sample 19 had a somewhat low degree of tackiness but had a sufficient degree of tackiness for temporal fixation. From these results, the coefficient of static friction is preferably 8.0 or more. The hardness of sample 20 is 60 in terms of E hardness and 90 or more in terms of OO hardness.

Samples 3, 6, and 9 had appropriate degrees of tackiness. Sample 22 tended to have an excessively high degree of tackiness, and it was difficult to detach the sample from the adherend without breaking the sample. In this case, the reworkability of, for example, the thermally conductive sheet, a heat-generating body, and a heat-dissipating body is degraded, which is not preferred. From these results, the coefficient of static friction is preferably 8.0 to 20.0, more preferably 10.0 to 15.0.

Each of the samples excluding samples 20 and 21 had a high degree of tackiness. As a result, stable pulling, in which the maximum traction value is obtained at the initial stage of pulling and then the traction becomes constant, could not be performed. Thus, for each sample, the maximum traction was used as a traction used for the determination of the coefficient of static friction.

### REFERENCE SIGNS LIST

S horizontal stage
P test piece
W weight
T tape
G push-pull gauge

1. A thermally conductive sheet, comprising a sheet-like formed body produced by curing a mixed composition containing an uncured polymer matrix, a flat graphite powder, and a thermally conductive filler having an aspect ratio of 2 or less,
flat surfaces of particles of the flat graphite powder being aligned in a thickness direction of the sheet.

2. The thermally conductive sheet according to claim 1, wherein the uncured polymer matrix contains a liquid silicone serving as a main component and a curing agent.

3. The thermally conductive sheet according to claim 1, wherein the flat graphite powder is composed of an artificial graphite produced by thermal decomposition of a polymer film by firing.

4. The thermally conductive sheet according to claim 1, wherein the flat graphite powder has a specific surface area of 0.70 to 1.50 m²/g.

5. The thermally conductive sheet according to claim 1, wherein with respect to a particle size distribution of the flat graphite powder in terms of surface-area frequency, the flat graphite powder has a peak in a range of 20 to 400 μm, and a ratio of a maximum frequency in a range of 200 to 400 μm to a maximum frequency in a range of 20 to 150 μm is 0.2 to 2.0.

6. The thermally conductive sheet according to claim 1, wherein with respect to a particle size distribution of the flat graphite powder in terms of surface-area frequency, a surface-area frequency at 800 μm or more is 0.1% or less.

7. The thermally conductive sheet according to claim 1, wherein the thermally conductive filler has an average particle size of 0.5 to 35 μm.

8. The thermally conductive sheet according claim 1, wherein the mixed composition contains 75 to 135 parts by mass of the flat graphite powder and 250 to 700 parts by mass of the thermally conductive filler per 100 parts by mass of the uncured polymer matrix.

9. The thermally conductive sheet according to claim 1, wherein directions of normals to the flat surfaces of the particles of the flat graphite powder extend randomly and parallel to a flat surface of the thermally conductive sheet.

10. The thermally conductive sheet according to claim 1, wherein the thermally conductive sheet has a type OO hardness, specified by ASTM D2240, of 10 to 80, a thermal conductivity of 12 to 30 W/m·K in the thickness direction of the sheet, and a coefficient of static friction of 8.0 to 20.0 against a mirror-finished stainless steel surface.
